(19) United States
(12) Patent Application Publication
(10) Pub. No.: US 2025/0079116 A1
(43) Pub. Date: Mar. 6, 2025

(54) In-Vacuum Rotatable RF Component

(71) Applicant: Applied Materials, Inc., Santa Clara, CA (US)

(72) Inventors: Michael Mason Carrell, Leander, TX (US); Aaron P. Webb, Austin, TX (US); Jason M. Schaller, Austin, TX (US); William H. Park, JR., Marblehead, MA (US); David Blahnik, Round Rock, TX (US); Wai-Ming Tam, Georgetown, MA (US)

(21) Appl. No.: 18/239,988

(22) Filed: Aug. 30, 2023

(51) Int. Cl. H01J 37/20; C23C 14/48; H01J 37/317

(52) U.S. Cl. CPC H01J 37/20; C23C 14/48; H01J 37/3171; H01J 2237/0266; H01J 2237/0473; H01J 2237/166; H01J 2237/20214

(57) ABSTRACT

An apparatus that may be used to allow the rotation of a component that passes through a wall of a vacuum chamber is disclosed. The apparatus includes a rotatable shaft through which the component passes. The rotatable shaft is held in place using a holder, which retains a portion of the rotatable shaft. In some embodiments, the holder is affixed to a plate, which is then affixed to the chamber wall. The plate has an opening which is aligned to the opening in the chamber wall. A portion of the rotatable shaft passes through the opening in the plate and vacuum seals are disposed between the rotatable shaft and the plate. This apparatus may be used to allow use of rotatable components in an ion implanter.

### FIELD

Embodiments of the present disclosure relate to an apparatus that may be used to rotate a component, such as an RF component, within a vacuum chamber.

### BACKGROUND

Many semiconductor processes utilize vacuum chambers. Typically, most of the equipment that is used to perform the semiconductor process is disposed in the vacuum chamber. There may be conduits that pass from an atmospheric environment through the walls of the vacuum chamber. This may be accomplished using a vacuum seal, such as a O-ring. These conduits may include power signals, electrical signals, gas lines, fluid conduits, and others. In most embodiments, the interface used for these conduits is static. In other words, the gas lines, fluid connections and electrical wires remain fixed relative to the wall of the vacuum chamber.

However, there may be instances where relative movement, such as rotation, between the conduit and the wall of the vacuum chamber may be desirable. For example, it may be desirable to rotate a component to achieve a desired electrical or magnetic field. Currently, this is performed by venting the vacuum chamber, adjusting the component and then returning the vacuum chamber to vacuum again. This is time consuming and inefficient.

Therefore, it would be beneficial if there was a system that allowed a component, which passes through the wall of a vacuum chamber, to be rotated with respect to that wall. Further, it would be desirable if the vacuum chamber maintained vacuum during this rotation.

### SUMMARY

An apparatus that may be used to allow the rotation of a component that passes through a wall of a vacuum chamber is disclosed. The apparatus includes a rotatable shaft through which the component passes. The rotatable shaft is held in place using a holder, which retains a portion of the rotatable shaft. In some embodiments, the holder is affixed to a plate, which is then affixed to the chamber wall. The plate has an opening which is aligned to the opening in the chamber wall. A portion of the rotatable shaft passes through the opening in the plate and vacuum seals are disposed between the rotatable shaft and the plate. This apparatus may be used to allow use of rotatable components in an ion implanter.

According to one embodiment, an apparatus to allow rotation of a component within a vacuum chamber is disclosed. The apparatus comprises a plate having an opening configured to be affixed to a chamber wall having an opening, wherein the opening of the plate aligns with the opening in the chamber wall; a rotatable shaft, having an extended portion that extends into the opening of the plate, and a retaining portion disposed adjacent to the extended portion, wherein a diameter of the retaining portion is larger than a diameter of the extended portion; a holder having a linear section adjacent to the plate, and an overhang disposed at an end of the linear section and extending radially inward, such that a diameter of the linear section is greater than the diameter of the retaining portion and a diameter of the overhang is smaller than the diameter of the retaining portion, so as to hold the retaining portion between the holder and the plate; a component disposed in a feedthrough in the rotatable shaft and configured to rotate with the rotatable shaft, extending through the opening in the chamber wall; and a first vacuum seal disposed between the extended portion and the plate. In some embodiments, the apparatus comprises a EMI gasket disposed between the extended portion and the plate. In some embodiments, the apparatus comprises an interface component disposed at a proximal end of the component and adjacent to an outer surface of the rotatable shaft; and a second vacuum seal disposed between the outer surface of the rotatable shaft and a back surface of the interface component. In certain embodiments, the apparatus comprises a EMI gasket disposed between the outer surface of the rotatable shaft and the back surface of the interface component. In certain embodiments, the interface component comprises a coaxial connector, wherein an outer conduit of the coaxial connector is electrically connected to the rotatable shaft; and an inner conduit of the coaxial connector is electrically connected to the component. In some embodiments, the component comprises an antenna. In some embodiments, the rotatable shaft comprises an exterior portion, adjacent to the retaining portion, having a smaller diameter than the diameter of the retaining portion, wherein the interface component is adjacent to the exterior portion.

According to another embodiment, an apparatus to allow rotation of a component within a vacuum chamber is disclosed. The apparatus comprises a chamber wall, defining the vacuum chamber, having an opening; a rotatable shaft, having an extended portion that extends into the opening of the chamber wall, and a retaining portion disposed adjacent to the extended portion, wherein a diameter of the retaining portion is larger than a diameter of the extended portion; a holder having a linear section adjacent to the chamber wall, and an overhang disposed at an end of the linear section and extending radially inward, such that a diameter of the linear section is greater than the diameter of the retaining portion and a diameter of the overhang is smaller than the diameter of the retaining portion, so as to hold the retaining portion between the holder and the chamber wall; a component disposed in a feedthrough in the rotatable shaft and configured to rotate with the rotatable shaft, extending through the opening in the chamber wall; and a first vacuum seal disposed between the extended portion and the chamber wall. In some embodiments, the apparatus comprises an interface component disposed at a proximal end of the component and adjacent to an outer surface of the rotatable shaft; and a second vacuum seal disposed between the outer surface of the rotatable shaft and a back surface of the interface component. In certain embodiments, the apparatus comprises a EMI gasket disposed between the outer surface of the rotatable shaft and the back surface of the interface component. In certain embodiments, the interface component comprises a coaxial connector, wherein an outer conduit of the coaxial connector is electrically connected to the rotatable shaft; and an inner conduit of the coaxial connector is electrically connected to the component. In certain embodiments, the component comprises an antenna.

According to another embodiment, an ion implanter is disclosed. The ion implanter comprises an ion source; a linear accelerator; and the apparatus described above; wherein the linear accelerator is disposed within the vacuum chamber and the component is a part of the linear accelerator.

According to another embodiment, an ion implanter is disclosed. The ion implanter comprises an ion source; and a linear accelerator, wherein the linear accelerator comprises one or more acceleration cavities, each acceleration cavity comprising a resonator coil and a tuner paddle to adjust a resonant frequency of a respective acceleration cavity, wherein the tuner paddle passes through an opening in one or more chamber walls, and into the acceleration cavity, wherein rotation of the tuner paddle is performed from outside a vacuum chamber defined by the one or more chamber walls, while maintaining vacuum. In some embodiments, the tuner paddle comprises an antenna. In certain embodiments, the antenna is affixed to a rotatable shaft, wherein a portion of the rotatable shaft is disposed between a holder and a plate, and the plate is affixed to an outer surface of the one of the one or more chamber walls, wherein vacuum seals are disposed between the rotatable shaft and the plate and between the plate and the one of the one or more chamber walls. In certain embodiments, a coaxial connector is disposed on an outer surface of the rotatable shaft, wherein an inner conduit of the coaxial connector is in communication with the antenna; and further comprising an additional vacuum seal disposed between the coaxial connector and the outer surface of the rotatable shaft. In certain embodiments, the ion implanter comprises an EMI gasket disposed between the coaxial connector and the outer surface of the rotatable shaft. In some embodiments, the tuner paddle is affixed to a rotatable shaft, wherein the rotatable shaft is disposed between a holder and an outer surface of the one of the one or more chamber walls, wherein and a first vacuum seal is disposed between the rotatable shaft and the one of the one or more chamber walls.

### BRIEF DESCRIPTION OF THE FIGURES

For a better understanding of the present disclosure, reference is made to the accompanying drawings, which are incorporated herein by reference and in which:

FIG. 1 shows a block diagram of an apparatus according to a first embodiment that may be used to allow rotation of a component that passes through a wall in a vacuum chamber;

FIG. 2 shows a block diagram of an apparatus according to a second embodiment that may be used to allow rotation of a component that passes through a wall in a vacuum chamber;

FIG. 3 shows a block diagram of an apparatus according to a third embodiment that may be used to allow rotation of a component that passes through a wall in a vacuum chamber;

FIG. 4 shows a block diagram of an apparatus according to a fourth embodiment that may be used to allow rotation of a component that passes through a wall in a vacuum chamber;

FIG. 5 shows a cross-sectional view of a specific embodiment of this apparatus that allows rotation of a loop antenna;

FIG. 6 shows a front view of the apparatus of FIG. 5; and

FIG. 7 shows an ion implanter that may utilize the component described herein.

### DETAILED DESCRIPTION

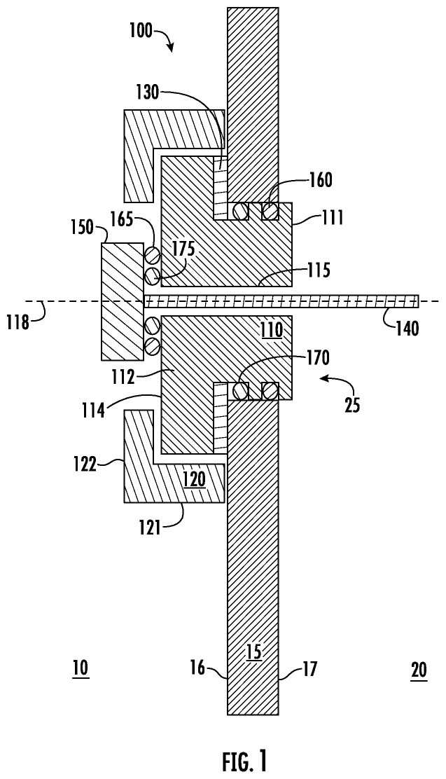

FIG. 1 shows a block diagram showing a cross section of an apparatus 100 that may be used to allow rotation of a component, such as an RF component, that passes through a wall of a vacuum chamber. In this figure, an atmospheric environment 10 is separated from the vacuum chamber 20 by a chamber wall 15. The chamber wall 15 may be a metal or plastic, such as stainless steel, aluminum, PEEK, or any other material that can be used as a sealing surface. The outer surface 16 of the chamber wall 15 is disposed in the atmospheric environment 10 and the inner surface 17 of the chamber wall 15 is disposed within the vacuum chamber 20. The pressure in the vacuum chamber 20 may be maintained at less than 1 Torr in some embodiments.

The chamber wall 15 includes an opening 25 that passes from the outer surface 16 to the inner surface 17. This opening 25 may be any suitable shape, such as circular, square or rectangular. In this embodiment, the opening 25 is circular and may have an opening diameter. In some embodiments, shown in FIGS. 1-3, a portion of the apparatus 100 described herein may extend into this opening 25.

The apparatus 100 includes a rotatable shaft 110. The rotatable shaft 110 may be made of any suitable material, such as aluminum, stainless steel, plastic or another material. The selection of the material may be based on the semiconductor process being performed within the vacuum chamber 20, as part of the rotatable shaft 110 is exposed to the vacuum chamber 20. In some embodiments, the rotatable shaft 110 may be an integral component having at least two different portions, each with a different diameter. The first portion, which is exposed to the vacuum chamber 20, is the extended portion 111. The extended portion 111 has a first diameter, which is smaller than the diameter of the opening 25. Further, at least a portion of the extended portion 111 of rotatable shaft 110 is disposed within the opening 25. In some embodiments, the extended portion 111 of the rotatable shaft 110 extends past the inner surface 17 of the chamber wall 15. The rotatable shaft 110 also has a second portion adjacent to the extended portion 111. This second portion is the retained portion 112, having a diameter that is larger than the diameter of the extended portion 111 and may also be larger than the diameter of the opening 25. In this way, when installed, the extended portion 111 of the rotatable shaft 110 may extend into the opening 25 in the chamber wall 15, but the retained portion 112 cannot.

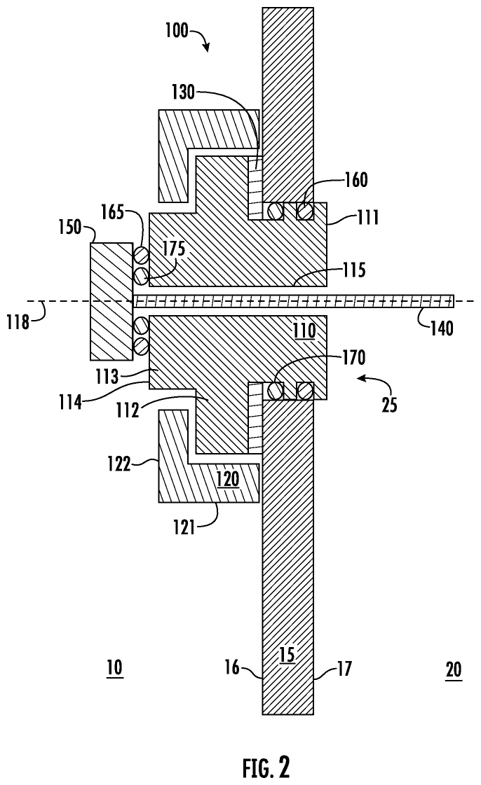

A holder 120 is used to hold the rotatable shaft 110 in place. The holder 120 may be constructed of a metal or may be a suitable thermoplastic polymer, such as PEEK. The holder 120 may be affixed directly to the chamber wall 15, as shown in FIGS. 1-2. The holder 120 has a linear section 121 that extends outward from the chamber wall 15 toward the atmospheric environment 10. The holder also includes an overhang 122 that extends radially inward from the linear section 121 toward the central axis 118 of the rotatable shaft 110. The diameter of the linear section 121 is larger than the diameter of the retained portion 112 of the rotatable shaft 110, while the diameter of the overhang 122 is smaller than that of the retained portion 112 so as to hold the rotatable shaft 110 in place between the chamber wall 15 and the overhang 122.

In certain embodiments, a low-friction surface 130, such as one or more Teflon washers, may be disposed between the retained portion 112 and the outer surface 16 of the chamber wall 15 to facilitate rotation of the rotatable shaft 110. In other embodiments, the low-friction surface 130 may not be present.

The rotatable shaft 110 may include a feedthrough 115, which passes through the entirety of the rotatable shaft 110 in the linear direction. In some embodiments, this feedthrough 115 may be disposed along the central axis 118 of the rotatable shaft 110. In other embodiments, the feedthrough 115 may not be disposed along the central axis 118. This feedthrough 115 is a hollow cylinder into which a component 140, such as an RF component, may be inserted. Note that the diameter of the feedthrough 115 may be larger than that of the component 140. Further, although not shown, an insulating material may be disposed between the component 140 and the rotatable shaft 110 to electrically isolate the component 140 from the rotatable shaft 110. In another embodiment, the diameter of the feedthrough 115 is sufficiently large that the gap between the component 140 and the rotatable shaft 110 acts as an insulator. An interface component 150 is attached to the end of the component 140 nearest the atmospheric environment 10. This interface component 150 allows for connection between the component 140 and another device, such as a power supply. This interface component 150 may be, for example, a connector. Note that this interface component 150 may have dimensions that are larger than the diameter of the feedthrough 115. In this way, there is overlap between the back surface of the interface component 150 and the outer surface 114 of the rotatable shaft 110. Further, the interface component 150 is affixed to the rotatable shaft 110 such that it rotates with the rotatable shaft 110. Thus, due to its connection to the interface component 150, the component 140 also rotates with the rotatable shaft 110.

To allow the apparatus 100 to function properly, there are vacuum seals and electromagnetic interference (EMI) gaskets disposed in the gaps between various components. A first vacuum seal 160 is located in the space between the chamber wall 15 and the extended portion 111 of the rotatable shaft 110. In some embodiments, this first vacuum seal 160 is an O-ring. In other embodiments, the first vacuum seal 160 may be a magnetic fluid seal. A second vacuum seal 165 is disposed between outer surface 114 of the rotatable shaft 110 and the interface component 150. The second vacuum seal 165 may be made of the same material as the first vacuum seal 160, or a different material. Note that the positions of the first vacuum seal 160 and the second vacuum seal 165 serve to isolate the vacuum chamber 20 from the atmospheric environment 10. A notch may be formed in the extended portion 111 or the chamber wall 15 (along the portion of the chamber wall 15 that defines the opening 25) to accommodate the first vacuum seal 160. Although not shown, a notch may be formed on the outer surface 114 of the rotatable shaft 110 or the interface component 150 to accommodate the second vacuum seal 165.

Additionally, EMI gaskets may be used to electrically isolate the component 140 (which may be an RF component) from the other parts of the system. In some embodiments, a first EMI gasket 170 may also be disposed in the space between the chamber wall 15 and the extended portion 111 of the rotatable shaft 110. In some embodiments, this first EMI gasket 170 may be a metal ring that may have a plurality of fingers. In certain embodiments, the metal may be beryllium copper. In another embodiment, the first EMI gasket 170 may be a conductive elastomer. A notch may be formed in the extended portion 111 or the chamber wall 15 to accommodate the first EMI gasket 170.

FIG. 1 shows the first vacuum seal 160 positioned such that the first EMI gasket 170 is disposed in the atmospheric environment 10. However, the placement of these two seals may be reversed, such that the first EMI gasket 170 is disposed in the vacuum chamber 20.

A second EMI gasket 175 may be disposed between outer surface 114 of the rotatable shaft 110 and the interface component 150. The second EMI gasket 175 may be made of the same material as the first EMI gasket 170, or a different material. Although not shown, a notch may be formed on the outer surface of the rotatable shaft 110 or the interface component 150 to accommodate the second EMI gasket 175. FIG. 1 shows the second vacuum seal 165 positioned such that the second EMI gasket 175 is disposed in the vacuum chamber 20. However, the placement of these two seals may be reversed, such that the second EMI gasket 175 is disposed in the atmospheric environment 10.

Note that in certain embodiments, the rotatable shaft 110 may be grounded. In this embodiment, the first EMI gasket 170 may not be utilized.

Note that the shape of the rotatable shaft 110 may differ from that shown in FIG. 1. For example, FIG. 2 shows a different embodiment. Identical components have been given the same reference designators and are as described above. As shown in FIG. 2, in addition to the extended portion 111 and the retained portion 112, there is an exterior portion 113. The exterior portion 113 is located in the atmospheric environment 10 and is adjacent to the retained portion 112. The exterior portion 113 may have a diameter smaller than the retained portion 112. Further, in certain embodiments, the exterior portion 113 may not be cylindrical, as long as it is smaller than the diameter of the overhang 122. This exterior portion 113 extends into the atmospheric environment 10 away from the retained portion 112. The exterior portion 113 may include a mechanism to allow it to be rotated by the user.

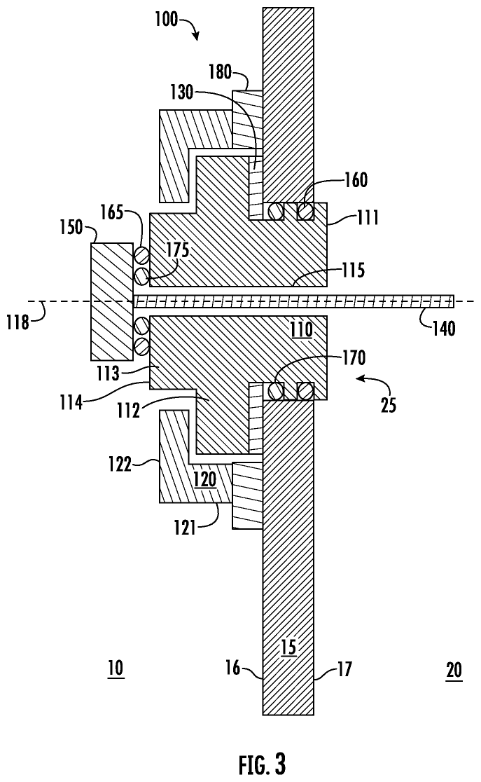

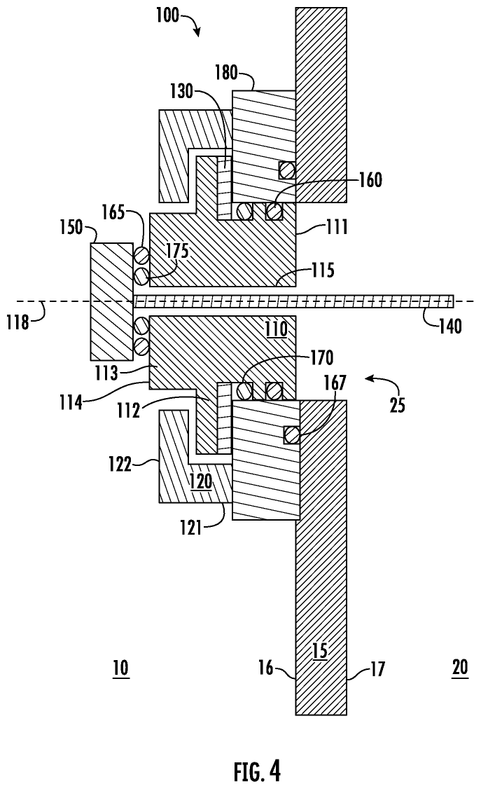

Further, FIGS. 1 and 2 both show the holder 120 affixed directly to the chamber wall 15. However, in other embodiments, the holder 120 may be affixed to a plate 180, that is then affixed to the chamber wall 15. FIGS. 3-4 show such a plate 180 that is affixed to the chamber wall 15. Components that appear in FIGS. 1-2 have been given the same reference designators and are as described above.

In FIG. 3, the plate 180 has an opening that is larger than the opening 25 of the chamber wall 15. Further, in this embodiment, the diameter of the opening in plate 180 is larger than or equal to the diameter of the linear section 121 of the holder 120 such that the retained portion 112 is positioned between the chamber wall 15 and the overhang 122. In this embodiment, the holder 120 is affixed to the plate 180. The rest of the apparatus 100 is as described above, where the extended portion 111 extends into the opening 25 of the chamber wall 15. Since the extended portion 111 extends into the opening 25 and includes the first vacuum seal 160, vacuum seals between the plate 180 and the chamber wall 15 may not be employed.

In FIG. 4, the plate 180 has an opening that may be similar in size to the diameter of the opening 25 in the chamber wall 15. In this embodiment, the diameter of the opening in plate 180 is smaller than the diameter of the linear section 121 of the holder 120 such that the retained portion 112 is positioned between the plate 180 and the overhang 122. Thus, the low-friction surface 130, if present, is disposed between the rotatable shaft 110 and the plate 180. In this embodiment, the extended portion 111 may not extend into the opening 25 of the chamber wall 15. However, it does extend into the opening in the plate 180. Thus, in this embodiment, the first vacuum seal 160 and the first EMI gasket 170 (if present) may be disposed between the extended portion 111 of the rotatable shaft 110 and the plate 180 (along the portion of the plate 180 that defines the opening). Notches may be formed in the extended portion 111 or the plate 180 to accommodate the first vacuum seal 160 and the first EMI gasket 170 (if present). Further, in this embodiment, a third vacuum seal 167 may be introduced between the plate 180 and the chamber wall 15.

Note that this implementation may be applicable to various sized openings 25 in the chamber wall 15 since there is no predefined relationship between the diameter of the extended portion 111 of the rotatable shaft 110 and the opening 25 in the chamber wall 15. Rather, the vacuum seal is made between the extended portion 111 and the plate 180.

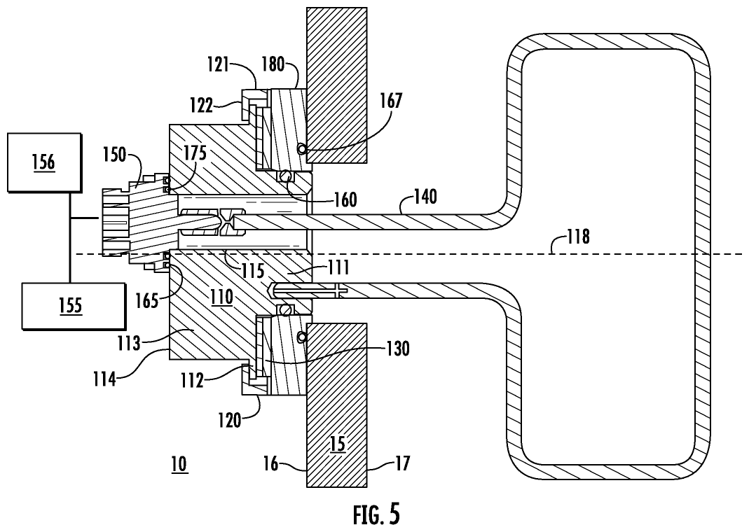

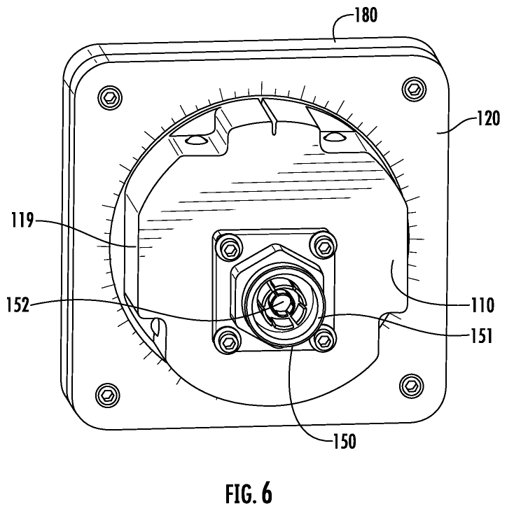

FIG. 5 shows a cross sectional view of a specific implementation of the apparatus 100 shown in FIG. 4. FIG. 6 shows a front view of this embodiment. In this embodiment, the component 140 that passes through the feedthrough 115 is an antenna, such as a loop antenna. The loop antenna may be constructed from copper or another suitable conductive material. The feedthrough 115 in the rotatable shaft 110 has a diameter that is sufficiently large such that there is no electrical contact between the component 140 and the rotatable shaft 110 in the feedthrough 115. Note as well that in this embodiment, the distal end of the loop antenna may be affixed and electrically connected to the rotatable shaft 110. In this embodiment, the feedthrough 115 is not located along the central axis 118 of the rotatable shaft 110; rather, the center line of the loop antenna is colinear with the central axis 118. A notch is created in the extended portion 111 to accommodate the first vacuum seal 160. Additionally, a notch is created in the plate 180 to accommodate the third vacuum seal 167. Lastly, in this embodiment, notches are created in the back surface of the interface component 150 to accommodate the second EMI gasket 175 and the second vacuum seal 165.

As best seen in FIG. 6, the interface component 150 is a connector, which may be a coaxial connector that includes an outer conduit 151 and an inner conduit 152. The outer conduit 151 is electrically in contact with the rotatable shaft 110. This outer conduit 151 may be grounded. In this scenario, the first EMI gasket 170 may be omitted since the rotatable shaft 110, the plate 180 and the chamber wall 15 are all at ground potential. The inner conduit 152 may be electrically connected to a RF power supply 155, which provides an RF signal to the inner conduit 152. The inner conduit 152 is electrically connected to the loop antenna, allowing the loop antenna to radiate electromagnetic energy into the vacuum chamber. This electromagnetic energy may be used as part of an ion implanter, an ion accelerator, other electromagnetic excitation devices, or another component. In some embodiments, more than 10 kW of RF power may be provided to the loop antenna. Further, in certain embodiments, the inner conduit 152 may be connected to a network analyzer 156 to monitor the performance of the loop antenna. The rest of FIG. 5 is similar to the description provided above with respect to FIG. 4. Note, as shown in FIG. 6, in some embodiments, the walls of the exterior portion 113 of the rotatable shaft 110 may not be round, but may include parallel straight walls 119. This may allow a wrench or similar device to be used to rotate the rotatable shaft 110. Note as well, that in some embodiments, the holder 120 may include markings that include the angle of rotation of the rotatable shaft 110 and the attached component 140. Thus, when manually actuated, the operator is able to determine the exact angle of rotation.

Although not shown, in other embodiments, the walls of the exterior portion 113 of the rotatable shaft 110 may be circular and include teeth such that a motor, such as a stepper motor, may be used to rotate the rotatable shaft 110.

While FIGS. 5-6 show the component that is being rotated within the vacuum chamber 20 as being a loop antenna, it is understood that this apparatus may be used to rotate any type of component. It may be used to rotate shafts, paddles, other types of antennas or any other components.

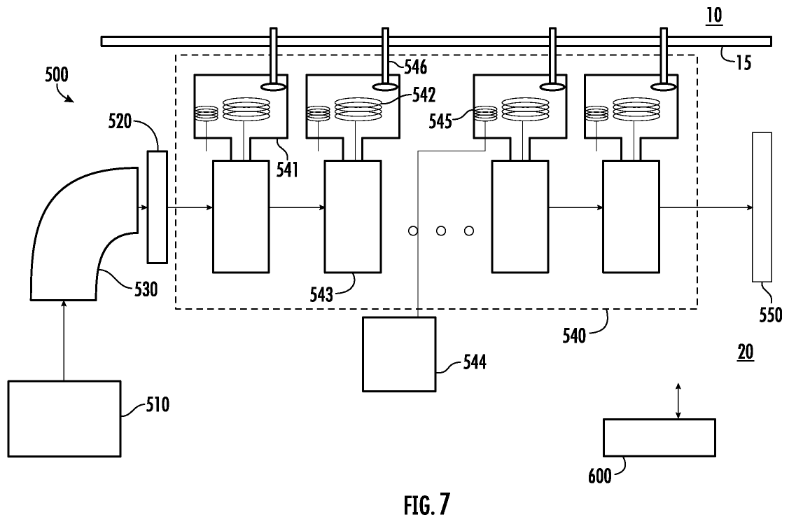

The component described herein may be used as part of an ion implanter. FIG. 7 shows one such ion implanter 500. An ion source 510, a mass analyzer 530, a buncher 520 and a linear accelerator 540, are disposed within the vacuum chamber 20. The ion source 510 may be any suitable ion source, such as, but not limited to, an indirectly heated cathode (IHC) source, a Bernas source, a capacitively coupled plasma source, an inductively coupled plasma source, or any other suitable device. The ion source 510 has an aperture through which ions may be extracted from the ion source 510. These ions may be extracted from the ion source 510 by applying a negative voltage to one or more electrodes, disposed outside the ion source 510, proximate the extraction aperture.

The ions may then enter a mass analyzer 530, which may be a magnet that allows ions having a particular mass to charge ratio to pass through. This mass analyzer 530 is used to separate only the desired ions. It is the desired ions that then enter the linear accelerator 540.

The desired ions then enter a buncher 520, which creates groups or bunches of ions that travel together. The buncher 520 may comprise a plurality of drift tubes, wherein at least one of the drift tubes may be supplied with an AC voltage. One or more of the other drift tubes may be grounded. The drift tubes that are supplied with the AC voltage may serve to accelerate and manipulate the ion beam into discrete bunches.

The linear accelerator 540 comprises one or more acceleration cavities 541. In certain embodiments, there may be between one and sixteen acceleration cavities 541 in the linear accelerator 540. Each acceleration cavity 541 comprises a resonator coil 542 that may be energized by electromagnetic fields created by an excitation coil 545. The excitation coil 545 is disposed in the acceleration cavity 541 with a respective resonator coil 542. The excitation coil 545 is energized by an excitation voltage, which may be a RF signal. The excitation voltage may be supplied by a respective RF generator 544. Each excitation coil 545 is tuned to a single resonant frequency. In other words, the excitation voltage applied to each excitation coil 545 may be independent of the excitation voltage supplied to any other excitation coil 545. Each excitation voltage is preferably modulated at the resonance frequency of its respective acceleration cavity 541. The magnitude and phase of the excitation voltage may be determined and changed by a controller 600, which is in communication with the RF generator 544. By disposing the resonator coil 542 in an acceleration cavity 541, the magnitude of the excitation voltage may be increased or phase shifted while keeping the amplitude the same.

Within each acceleration cavity 541, there may be a respective tuner paddle 546. The tuner paddle 546 may be rotatable so as to modify its position within the acceleration cavity 541. The position of the tuner paddle 546 may affect the resonant frequency of the acceleration cavity 541.

Each acceleration cavity 541 may be located in the vacuum chamber 20, adjacent to the chamber wall 15, such that the component 140 passes through the chamber wall 15 and into a respective acceleration cavity 541. As described above, the component 140 (see FIG. 5) may be an antenna, such as a loop antenna. Thus, in certain embodiments, the component 140 described above serves as the tuner paddle 546. In other embodiments, the component 140 may be a paddle. Thus, rotation of the component 140, which may be performed from outside the vacuum chamber 20, is performed to individually tune each acceleration cavity 541. As noted above, this rotation may be performed manually, or using an actuator, such as a motor. In other embodiments, the component 140 may serve a different purpose within the acceleration cavity 541, such as serving as the excitation coil 545.

When an excitation voltage is applied to the excitation coil 545, a voltage is induced on the resonator coil 542. The excitation voltage may be an RF voltage having a frequency between 13.56 MHz and 27 MHz. Further, the amplitude of the voltage may be between 9 kV and 170 kV. The result is that the resonator coil 542 in each acceleration cavity 541 is driven by a sinusoidal voltage. Each resonator coil 542 may be in electrical communication with a respective accelerator electrode 543. The ions pass through apertures in each accelerator electrode 543.

The entry of the bunch into a particular accelerator electrode 543 is timed such that the potential of the accelerator electrode 543 is negative as the bunch approaches, but switches to positive as the bunch passes through the accelerator electrode 543. In this way, the bunch is accelerated as it enters the accelerator electrode 543 and is repelled as it exits. This results in an acceleration of the bunch. This process is repeated for each accelerator electrode 543 in the linear accelerator 540. Each accelerator electrode increases the acceleration of the ions and can be measured.

After the bunch exits the linear accelerator 540, it is implanted into the workpiece 550.

Of course, the ion implanter 500 may include other components, such as an electrostatic scanner to create a ribbon beam, quadrupole elements, additional electrodes to accelerate or decelerate the beam and other elements.

A controller 600 may be used to control the ion implanter 500. The controller 600 may include a processing unit and a memory device. The processing unit may be a microprocessor, a signal processor, a customized field programmable gate array (FPGA), or another suitable unit. This memory device may be a non-volatile memory, such as a FLASH ROM, an electrically erasable ROM or other suitable devices. In other embodiments, the memory device may be a volatile memory, such as a RAM or DRAM. The memory device comprises instructions that enable the controller 600 to control the linear accelerator 540 and optionally the tuner paddle 546.

The embodiments described above in the present application may have many advantages. As explained above, rotation of a component within a vacuum chamber typically is preceded by venting air to the vacuum chamber. The component is then rotated to the desired new position and the vacuum chamber is pumped down again. This is very time consuming and precludes use of rotating components in a production operation. By utilizing the rotatable shaft with the vacuum seals and EMI gaskets as described above, this feature is readily achievable. Further, this apparatus also allows for fine tuning of the system that is disposed in the vacuum chamber while the vacuum chamber remains at vacuum. For example, the system within the vacuum chamber may be an ion implantation system. This apparatus allows rotation of an antenna, paddle or other component that may serve to tune the ion implantation system.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An apparatus to allow rotation of a component within a vacuum chamber, comprising:
a plate having an opening configured to be affixed to a chamber wall having an opening, wherein the opening of the plate aligns with the opening in the chamber wall;
a rotatable shaft, having an extended portion that extends into the opening of the plate, and a retained portion disposed adjacent to the extended portion, wherein a diameter of the retained portion is larger than a diameter of the extended portion;
a holder having a linear section adjacent to the plate, and an overhang disposed at an end of the linear section and extending radially inward, such that a diameter of the linear section is greater than the diameter of the retained portion and a diameter of the overhang is smaller than the diameter of the retained portion, so as to hold the retained portion between the holder and the plate;
a component disposed in a feedthrough in the rotatable shaft and configured to rotate with the rotatable shaft, extending through the opening in the chamber wall; and
a first vacuum seal disposed between the extended portion and the plate.

2. The apparatus of claim 1, further comprising a EMI gasket disposed between the extended portion and the plate.

3. The apparatus of claim 1, further comprising an interface component disposed at a proximal end of the component and adjacent to an outer surface of the rotatable shaft; and
a second vacuum seal disposed between the outer surface of the rotatable shaft and a back surface of the interface component.

4. The apparatus of claim 3, further comprising a EMI gasket disposed between the outer surface of the rotatable shaft and the back surface of the interface component.

5. The apparatus of claim 3, wherein the interface component comprises a coaxial connector, wherein an outer conduit of the coaxial connector is electrically connected to the rotatable shaft; and an inner conduit of the coaxial connector is electrically connected to the component.

6. The apparatus of claim 3, wherein the component comprises an antenna.

7. The apparatus of claim 3, wherein the rotatable shaft comprises an exterior portion, adjacent to the retained portion, having a smaller diameter than the diameter of the retained portion, wherein the interface component is adjacent to the exterior portion.

8. An ion implanter, comprising:
an ion source;
a linear accelerator; and
the apparatus of claim 1;
wherein the linear accelerator is disposed within the vacuum chamber and the component is a part of the linear accelerator.

9. An apparatus to allow rotation of a component within a vacuum chamber, comprising:
a chamber wall, defining the vacuum chamber, having an opening;
a rotatable shaft, having an extended portion that extends into the opening of the chamber wall, and a retained portion disposed adjacent to the extended portion, wherein a diameter of the retained portion is larger than a diameter of the extended portion;
a holder having a linear section adjacent to the chamber wall, and an overhang disposed at an end of the linear section and extending radially inward, such that a diameter of the linear section is greater than the diameter of the retained portion and a diameter of the overhang is smaller than the diameter of the retained portion, so as to hold the retained portion between the holder and the chamber wall;
a component disposed in a feedthrough in the rotatable shaft and configured to rotate with the rotatable shaft, extending through the opening in the chamber wall; and
a first vacuum seal disposed between the extended portion and the chamber wall.

10. The apparatus of claim 9, further comprising an interface component disposed at a proximal end of the component and adjacent to an outer surface of the rotatable shaft; and
a second vacuum seal disposed between the outer surface of the rotatable shaft and a back surface of the interface component.

11. The apparatus of claim 10, further comprising a EMI gasket disposed between the outer surface of the rotatable shaft and the back surface of the interface component.

12. The apparatus of claim 10, wherein the interface component comprises a coaxial connector, wherein an outer conduit of the coaxial connector is electrically connected to the rotatable shaft; and an inner conduit of the coaxial connector is electrically connected to the component.

13. The apparatus of claim 10, wherein the component comprises an antenna.

14. An ion implanter, comprising:
an ion source;
a linear accelerator; and
the apparatus of claim 9;
wherein the linear accelerator is disposed within the vacuum chamber and the component is a part of the linear accelerator.

15. An ion implanter, comprising:
an ion source; and
a linear accelerator, wherein the linear accelerator comprises one or more acceleration cavities, each acceleration cavity comprising a resonator coil and a tuner paddle to adjust a resonant frequency of a respective acceleration cavity, wherein the tuner paddle passes through an opening in one or more chamber walls, and into the acceleration cavity, wherein rotation of the tuner paddle is performed from outside a vacuum chamber defined by the one or more chamber walls, while maintaining vacuum.

16. The ion implanter of claim 15, wherein the tuner paddle comprises an antenna.

17. The ion implanter of claim 16, wherein the antenna is affixed to a rotatable shaft, wherein a portion of the rotatable shaft is disposed between a holder and a plate, and the plate is affixed to an outer surface of the one of the one or more chamber walls, wherein vacuum seals are disposed between the rotatable shaft and the plate and between the plate and the one of the one or more chamber walls.

18. The ion implanter of claim 17, wherein a coaxial connector is disposed on an outer surface of the rotatable shaft, wherein an inner conduit of the coaxial connector is in communication with the antenna; and further comprising an additional vacuum seal disposed between the coaxial connector and the outer surface of the rotatable shaft.

19. The ion implanter of claim 18, further comprising an EMI gasket disposed between the coaxial connector and the outer surface of the rotatable shaft.

20. The ion implanter of claim 15, wherein the tuner paddle is affixed to a rotatable shaft, wherein the rotatable shaft is disposed between a holder and an outer surface of the one of the one or more chamber walls, wherein and a first vacuum seal is disposed between the rotatable shaft and the one of the one or more chamber walls.
